(19) United States
(12) Patent Application Publication
(10) Pub. No.: US 2017/0247571 A1
(43) Pub. Date: Aug. 31, 2017

(54) MANUFACTURING METHOD FOR FILM AND MANUFACTURING METHOD FOR LIQUID EJECTION HEAD

(71) Applicant: CANON KABUSHIKI KAISHA, Tokyo (JP)

(72) Inventors: Miho Ishii, Kawasaki-shi (JP); Etsuko Sawada, Tokyo (JP)

(21) Appl. No.: 15/414,180

(22) Filed: Jan. 24, 2017

(30) Foreign Application Priority Data
Feb. 29, 2016 (JP) 2016-037874

(51) Int. Cl. C09D 183/08; C23C 16/56; B41J 2/16; C09D 183/14

(52) U.S. Cl. CPC C09D 183/08; C09D 183/14; C23C 16/56; B41J 2/164; B41J 2/162

(57) ABSTRACT

Provided is a manufacturing method for a film containing a condensate of hydrolyzable silane compounds, the manufacturing method including: forming, on a base material, a layer containing a condensate of a hydrolyzable silane compound having an epoxy group and a hydrolyzable silane compound having a fluorine-containing group, and a solvent; and curing the layer, the solvent containing one of ethanol and methanol serving as a first alcohol component, and at least one kind of alcohol having a boiling point of from 90° C. to 200° C. serving as a second alcohol component, the solvent having a content of the second alcohol component of from 2.00 mass % to 60.00 mass %, the condensate having a degree of condensation of from 20% to 80%.

### BACKGROUND OF THE INVENTION

### Field of the Invention

The present invention relates to a manufacturing method for a film and a manufacturing method for a liquid ejection head.

### Description of the Related Art

In a liquid ejection head, characteristics of a surface in which an ejection orifice is formed are extremely important for providing satisfactory liquid droplet ejection performance. When a liquid pool remains in the vicinity of the ejection orifice on the surface in which the ejection orifice is formed, a flying direction of a liquid droplet is deflected or an ejection speed of the liquid droplet lowers in some cases. As one of the methods of solving such problem in a liquid ejection head to be used for ejecting a water-containing liquid, such as aqueous ink, there is given a method involving subjecting the surface in which the ejection orifice is formed, including a region at an edge of the ejection orifice, to water-repellent treatment.

In general, a silicone-based compound, a fluorine-containing organic compound, or the like is used as a material for the water-repellent treatment of the surface in which the ejection orifice is formed. The fluorine-containing organic compound is suitable for water-repellent treatment for an ink jet recording head configured to eject aqueous liquid droplets containing various solvents and colorants. Hitherto, as the fluorine-containing organic compound expressing satisfactory water repellency, there are known fluorine-containing organic compounds such as a perfluoroalkyl group-containing compound and a perfluoropolyether group-containing compound.

In Japanese Patent Application Laid-Open No. 2007-518587, as a fluorine-containing organic compound to be used for liquid repellent processing on the surface of an ink jet recording head in which the ejection orifice is formed, there is disclosed a condensation product of a hydrolyzable silane compound having a fluorine-containing group and a hydrolyzable silane compound having a cationically polymerizable group. In Japanese Patent Application Laid-Open No. 2007-518587, as a solvent for diluting the condensation product to provide a coating liquid for the liquid repellent processing, there is disclosed a mixed solvent of ethanol and 2-butanol.

### SUMMARY OF THE INVENTION

According to one aspect of the present invention, there is provided a manufacturing method for a film containing a condensate of hydrolyzable silane compounds, the manufacturing method including:

forming, on a base material, a layer containing a condensate of a hydrolyzable silane compound having an epoxy group and a hydrolyzable silane compound having a fluorine-containing group, and a solvent; and

curing the layer,

the solvent containing one of ethanol and methanol serving as a first alcohol component, and at least one kind of alcohol having a boiling point of from 90° C. to 200° C. serving as a second alcohol component, the solvent having a content of the second alcohol component of from 2.00 mass % to 60.00 mass %,

the condensate having a degree of condensation of from 20% to 80%.

According to another aspect of the present invention, there is provided a manufacturing method for a liquid ejection head including an ejection orifice and a film containing a condensate of hydrolyzable silane compounds on a surface in which the ejection orifice is formed, the manufacturing method including:

forming, on a base material, a layer containing a condensate of a hydrolyzable silane compound having an epoxy group and a hydrolyzable silane compound having a fluorine-containing group, and a solvent; and

curing the layer,

the solvent containing one of ethanol and methanol serving as a first alcohol component, and at least one kind of alcohol having a boiling point of from 90° C. to 200° C. serving as a second alcohol component, the solvent having a content of the second alcohol component of from 2.00 mass % to 60.00 mass %,

the condensate having a degree of condensation of from 20% to 80%.

Further features of the present invention will become apparent from the following description of exemplary embodiments with reference to the attached drawings.

### BRIEF DESCRIPTION OF THE DRAWINGS

FIG. 1A and FIG. 1B are schematic views of an ink jet recording head according to an embodiment in which a film according to the present invention is applied as a water-repellent and antifouling film.

FIG. 2A, FIG. 2B, and FIG. 2C are explanatory views of a manufacturing method for an ink jet recording head according to an embodiment in which the film according to the present invention is applied as a water-repellent and antifouling film.

### DESCRIPTION OF THE EMBODIMENTS

Preferred embodiments of the present invention will now be described in detail in accordance with the accompanying drawings.

In the formation of a film containing a fluorine-containing organic compound on a surface to be treated, a method involving applying a coating liquid containing the fluorine-containing organic compound and a solvent onto the surface to be treated is generally utilized. Water-repellent treatment of the surface to be treated may be performed by applying the coating liquid onto the surface to be treated, followed by drying, to form a water-repellent film. The use of the fluorine-containing organic compound having water repellency can impart water repellency to the film on the surface to be treated.

However, when the amount of the solvent contained in the coating liquid is large, aggregation of the fluorine-containing organic compound may occur to cause application unevenness on the surface to be treated. This tendency is observed in, for example, the case where the amount of the coating liquid is increased for the purpose of covering a step with the coating liquid or increasing the layer thickness of the coating liquid, or the case where the amount of the solvent in the coating liquid is increased as a result of the use of a more diluted coating liquid. The coating liquid containing the fluorine-containing organic compound already has low surface tension itself, and hence it is difficult to further lower the surface tension of the coating liquid itself through the use of a surfactant or the like to alleviate the application unevenness on the surface to be treated.

In order to further improve the characteristics of the film containing the fluorine-containing organic compound to be obtained by the application method, it is important to prevent the above-mentioned aggregation of the fluorine-containing compound in the coating liquid.

In addition, also in the case of utilizing a condensate of hydrolyzable silane compounds for liquid repellent processing on the surface of a liquid ejection head in which an ejection orifice is formed as in Japanese Patent Application Laid-Open No. 2007-518587, further improvement of the application property of the coating liquid is important for further improving the performance of the liquid ejection head.

Meanwhile, in recent years, from the viewpoint of high durability, high water repellency, or a reduction in environmental burden, a fluorine-containing organic compound having a perfluoro(poly)ether group in place of the perfluoroalkyl group has started to be utilized for surface treatment. However, the fluorine-containing organic compound having a perfluoro(poly)ether group may be more liable to cause the above-mentioned aggregation depending on application conditions.

It is an object of the present invention to provide a manufacturing method for a film, capable of achieving the improvement of characteristics of a film containing a fluorine-containing organic compound to be formed on a base material.

It is another object of the present invention to provide a manufacturing method for a liquid ejection head, capable of forming a film containing a fluorine-containing organic compound improved in characteristics of the film on the surface of a liquid ejection head in which an ejection orifice is formed.

It is still another object of the present invention to provide a surface treatment method for a liquid ejection head, capable of further improving characteristics of a film containing a fluorine-containing organic compound for use in surface treatment of the surface of a liquid ejection head in which an ejection orifice is formed.

According to one aspect of the present invention, a film improved in characteristics by being more uniformized through the suppression of the occurrence of the application unevenness due to the aggregation of the fluorine-containing organic compound component contained in the coating liquid on a base material can be formed on the base material.

The present invention is described in detail below.

A manufacturing method for a film according to the present invention includes the steps of applying, onto a base material, a coating liquid containing a condensate of hydrolyzable silane compounds (hereinafter referred to as “condensate”) and a solvent, and curing the resultant applied layer to form a film.

The condensate may be obtained by subjecting a material for condensate formation to a condensation reaction. The material for condensate formation contains at least the following component (A) and component (B):

(A) one kind or a combination of two or more kinds of hydrolyzable silane compounds each having an epoxy group; and

(B) one kind or a combination of two or more kinds of hydrolyzable silane compounds each having a fluorine-containing group.

Further, the solvent contained in the coating liquid contains one of ethanol and methanol serving as a first alcohol component, and at least one kind of alcohol having a boiling point of from 90° C. to 200° C. serving as a second alcohol component. The content of the second alcohol component in the solvent contained in the coating liquid is selected from the range of from 2.00 mass % to 60.00 mass %.

The manufacturing method for a film according to the present invention may further include the step of forming the condensate by subjecting the material for condensate formation to a reaction in the presence of at least water and ethanol.

According to the present invention, the film containing the condensate can be formed on a substrate uniformly without unevenness. According to the present invention, a more homogenized film can be obtained on the base material, and further improvement of the characteristics of the film as a whole can be achieved. In addition, in the present invention, the condensate using at least the above-mentioned two components in its material is used as a constituent material for the film, and homogenization of the film can be achieved. Accordingly, a film having high durability can be obtained.

First, each of the hydrolyzable silane compounds serving as the material for condensate formation is described.

[Component (A)]

The component (A) is a component mainly for imparting curability to the condensate, and is not particularly limited as long as the component (A) is a hydrolyzable silane compound having an epoxy group capable of forming the condensate of interest with the component (B). In accordance with such purpose, a compound selected from commercially available or known hydrolyzable silane compounds each having an epoxy group may be used.

As a preferred compound for the component (A), there may be given a compound represented by the following formula (1).

R_{C}—SiX¹ₐR¹₍₃₋ₐ₎ Formula (1):

In the formula (1), R_{C} represents a non-hydrolyzable substituent having an epoxy group, R¹ represents a non-hydrolyzable substituent, and X¹ represents a hydrolyzable substituent. a represents an integer of from 1 to 3. a represents preferably 2 or 3, more preferably 3.

An example of R_{C} may be a linear or branched alkyl group having a glycidyl group or a glycidyloxy group and having 1 to 20 carbon atoms. Examples of the glycidyl group- or glycidyloxy group-substituted alkyl group include a glycidoxypropyl group, a 2-(3,4-epoxycyclohexyl)ethyl group, and an epoxycyclohexylethyl group. Of those, a γ-glycidoxypropyl group and an epoxycyclohexylethyl group are preferred.

Examples of R¹ include a linear or branched alkyl group having 1 to 20 carbon atoms and a phenyl group.

Examples of X¹ include a halogen atom, an alkoxy group, an amino group, and a hydrogen atom. Examples of the halogen atom may include F, Cl, Br, and I.

X¹ preferably represents a linear or branched alkoxy group having 1 to 3 carbon atoms, such as a methoxy group, an ethoxy group, or a propoxy group, from the viewpoint that a group eliminated by a hydrolysis reaction does not inhibit a cationic polymerization reaction and reactivity is easy to control.

When the compound of the formula (1) has a plurality of R¹'s, the plurality of R¹'s each independently represent the above-mentioned meaning. When the compound of the formula (1) has a plurality of X¹'s, the plurality of X¹'s each independently represent the above-mentioned meaning.

In addition, for example, a compound that has been partially converted to a hydroxy group by hydrolysis, or that has formed a siloxane bond by dehydration condensation may be used.

[Component (B)]

The component (B) is a component mainly for imparting, to the condensate, characteristics resulting from the introduction of a fluorine-containing group, such as water repellency, and is not particularly limited as long as the component (B) is a hydrolyzable silane compound having a fluorine-containing group capable of forming the condensate of interest with the component (A). In accordance with such purpose, a compound selected from commercially available or known hydrolyzable silane compounds each having a fluorine-containing group may be used as the component (B).

The component (B) is preferably a hydrolyzable silane compound having a non-hydrolyzable fluorine-containing group as the fluorine-containing group. Examples of the non-hydrolyzable fluorine-containing group may include a linear or branched perfluoroalkyl group and a linear or branched perfluoro(poly)ether group. Therefore, the component (B) may be prepared from one or more kinds selected from: (I) a hydrolyzable silane compound having a linear or branched perfluoroalkyl group; and (II) a hydrolyzable silane compound having a linear or branched perfluoro(poly)ether group.

A preferred hydrolyzable silane compound having a perfluoroalkyl group is a hydrolyzable silane compound represented by the following formula (2).

R_{f}SiX²_{b}R²_{(3-b)} Formula (2):

In the formula (2), R_{f} represents a non-hydrolyzable substituent having 1 to 30 fluorine atoms each bonded to a carbon atom, R² represents a non-hydrolyzable substituent, and X² represents a hydrolyzable substituent. b represents an integer of from 1 to 3, preferably 2 or 3, particularly preferably 3.

Examples of X² may include a hydrogen atom, a halogen atom, an alkoxy group, an aryloxy group, an acyloxy group, and an alkylcarbonyl group.

Examples of the halogen atom may include F, Cl, Br, and I.

The alkoxy group is preferably a linear or branched alkoxy group having 1 to 6 carbon atoms. Examples of such alkoxy group may include a methoxy group, an ethoxy group, a n-propoxy group, an isopropoxy group, a n-butoxy group, a sec-butoxy group, an isobutoxy group, and a tert-butoxy group.

The aryloxy group is preferably an aryloxy group having 6 to 10 carbon atoms. An example of such aryloxy group may be a phenoxy group.

The acyloxy group is preferably an acyloxy group having 1 to 6 carbon atoms. Examples of such acyloxy group may include an acetoxy group and a propynyloxy group.

The alkylcarbonyl group is preferably an alkylcarbonyl group having 2 to 7 carbon atoms. An example of such alkylcarbonyl group may be an acetyl group.

Of those, a linear or branched alkoxy group, such as a methoxy group, an ethoxy group, or a propoxy group, is preferred as X².

The non-hydrolyzable substituent represented by R² may contain a functional group, but is preferably a group containing no functional group. Preferred examples of R² may include a linear or branched alkyl group having 1 to 20 carbon atoms and a phenyl group.

When the compound of the formula (2) has a plurality of R²'s, the plurality of R²'s each independently represent the above-mentioned meaning. When the compound of the formula (2) has a plurality of X²'s, the plurality of X²'s each independently represent the above-mentioned meaning.

The structure of the non-hydrolyzable substituent R_{f} having a fluorine atom is not limited as long as the action and effect of interest can be obtained. A particularly preferred example of the group R_{f} may be a group represented by CF₃(CF₂)ᵥ-E-. In the formula, v represents an integer of from 0 to 20, preferably from 3 to 15, more preferably from 5 to 11. E represents a divalent organic group, and contains 10 or less carbon atoms. Preferred examples of E may include a divalent alkylene group and a divalent alkyleneoxy group each having up to 6 carbon atoms. Examples of such divalent organic group may include linear or branched alkylene groups or alkyleneoxy groups each having 1 to 4 carbon atoms, such as a methylene group, an ethylene group, a propylene group, a butylene group, a methyleneoxy group, an ethyleneoxy group, a propyleneoxy group, and a butyleneoxy group. Of those, an ethylene group is particularly preferred as E.

Specific examples of the compound of the formula (2) include C₂F₅—C₂H₄—SiX³₃, C₄F₉—C₂H₄—SiX³₃, C₆F₁₃—C₂H₄—SiX³₃, C₈F₁₇—C₂H₄—SiX³₃, C₁₀F₂₁—C₂H₄—SiX³₃, and C₁₂F₂₅—C₂H₄—SiX³₃ (in the formulae, X³'s each independently represent a methoxy group or an ethoxy group).

Next, the hydrolyzable silane compound having a perfluoro(poly)ether group is described.

The hydrolyzable silane compound having a perfluoro(poly)ether group is not particularly limited but is preferably at least one kind of compounds represented by the following formulae (3), (4), (5), and (6).

F—Rₚ¹-A¹-SiX⁴_{c}Y¹_{(3-c)} Formula (3):

R³_{(3-d)}X⁵_{d}Si-A²-Rₚ²-A³-SiX⁶ₑY²₍₃₋ₑ₎ Formula (4):

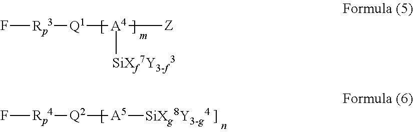

In the formulae (3) to (6): Rₚ¹ to Rₚ⁴ each independently represent a perfluoro(poly)ether group, A¹ to A⁵ each independently represent an organic bonding group having 1 to 12 carbon atoms, X⁴ to X⁸ each independently represent a hydrolyzable substituent, and Y¹ to Y⁴ and R³ each independently represent a non-hydrolyzable substituent; Z represents a hydrogen atom or an alkyl group, Q¹ and Q² each independently represent a divalent or trivalent bonding group, provided that when Q² is divalent, n=1, and that when Q² is trivalent, n=2, c to g each independently represent an integer of from 1 to 3, and m represents an integer of from 1 to 4; and units represented by -[A⁴(SiX⁷_{f}Y³_{(3-f)})]— when n represents 2 each independently have the above-mentioned meaning, and units represented by -A⁵-SiX⁵_{g}Y⁴_{(3-g)} when m represents from 2 to 4 each independently have the above-mentioned meaning.

X⁴ to X⁸ in the formulae (3) to (6) each independently represent, for example, a halogen atom, an alkoxy group, an amino group, or a hydrogen atom. Examples of the halogen atom may include F, Cl, Br, and I. X⁴ to X⁸ each preferably represent a linear or branched alkoxy group having 1 to 3 carbon atoms, such as a methoxy group, an ethoxy group, or a propoxy group, from the viewpoint that a group eliminated by a hydrolysis reaction does not inhibit a cationic polymerization reaction and reactivity is easy to control. The non-hydrolyzable substituents Y¹ to Y⁴ and R³ are each independently, for example, a linear or branched alkyl group having 1 to 20 carbon atoms or a phenyl group. Examples of the alkyl group represented by Z include linear or branched alkyl groups each having 1 to 3 carbon atoms, such as a methyl group, an ethyl group, and a propyl group. Q¹ and Q² each independently represent, for example, a carbon atom or a nitrogen atom.

An example of the organic bonding group having 1 to 12 carbon atoms represented by any one of A¹ to A⁵ may be a substituted or unsubstituted, linear or branched alkylene group having 1 to 12 carbon atoms. As a substituent of the alkylene group, there is given at least one kind of an ether group, a phenyl group, and a hydroxy group. In addition, examples of the alkylene group include linear or branched alkylene groups each having 1 to 3 carbon atoms, such as a methylene group, an ethylene group, and a propylene group.

The perfluoro(poly)ether group represented by any one of Rₚ¹ to Rₚ⁴ in the formulae (3) to (6) is a group having a unit formed of a perfluoroalkyl group and an oxygen atom. The “perfluoro(poly)ether group” refers to a “perfluoroether group” having one unit or a “perfluoropolyether group” in which two or more units are linked. When the perfluoro(poly)ether group has two or more units, the two or more units may be identical to each other, or the two or more units may include one or two or more combinations of different units.

The perfluoro(poly)ether group is preferably a group represented by the following formula (7).

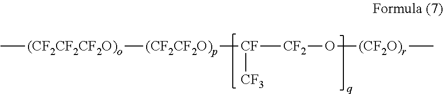

In the formula (7), o, p, q, and r each independently represent an integer of 0 or 1 or more, and at least one of o, p, q, and r represents an integer of 1 or more.

The number of repeating units in the perfluoro(poly)ether group, e.g., each of o, p, q, and r in the case of the formula (7), is preferably an integer of from 1 to 30, more preferably an integer of from 3 to 20 from the viewpoint of obtaining satisfactory characteristics such as water repellency and solubility in the solvent.

The average molecular weight of the perfluoro(poly)ether groups of a mixture of two or more kinds of the compounds represented by the formulae (3), (4), (5), and (6) is preferably from 500 to 5,000, more preferably from 500 to 2,000. In many cases, a compound having a perfluoro(poly)ether group is characteristically a mixture of compounds different from each other in the number of repeating units (e.g., at least one of o, p, q, and r in the formula (7)). The average molecular weight of the perfluoro(poly)ether groups refers to the average of the sum of the molecular weights of moieties represented by the repeating units in the formula (7) with respect to the total number of repeating units in the formula (7) contained in the mixture of two or more kinds of compounds each having a perfluoro(poly)ether group, i.e., a number average molecular weight.

The average molecular weight is a value obtained by MALDI-MS measurement.

Preferred specific examples of the hydrolyzable silane compound having a perfluoro(poly)ether group include compounds represented by the following formulae (8) to (12).

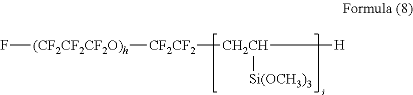

In the formula (8), h represents an integer of from 1 to 30, and i represents an integer of from 1 to 4.

F—(CF₂CF₂CF₂O)ⱼ—CF₂CF₂—CH₂O(CH₂)₃—Si(OCH₃)₃ Formula (9):

In the formula (9), j represents an integer of from 1 to 30.

(H₃CO)₃Si—CH₂CH₂CH₂—OCH₂CF₂—(OCF₂CF₂)ₖ—(OCF₂)₃—OCF₂CH₂O—CH₂CH₂CH₂—Si(OCH₃)₃ Formula (10):

In the formula (10), k and s each independently represent an integer of from 1 to 30.

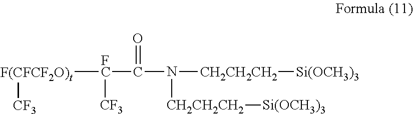

In the formula (11), t represents an integer of from 1 to 30.

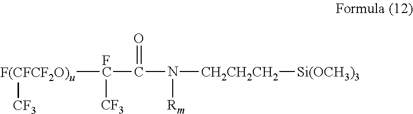

In the formula (12), Rm represents a methyl group or a hydrogen atom, and u represents an integer of from 1 to 30.

In the formula (8) to the formula (12), it is preferred that the numbers of repeating units represented by h, i, j, k, s, t, and u be each independently from 3 to 20, from the viewpoint of obtaining satisfactory characteristics such as water repellency and solubility in the solvent. In particular, when the condensation reaction is performed in a fluorine-free general-purpose solvent, such as an alcohol, each number of repeating units is preferably from 3 to 10 in order to enhance an affinity for the alcohol and other silane compounds.

Commercial products of the perfluoropolyether group-containing silane compound are, for example, “OPTOOL DSX” and “OPTOOL AES” manufactured by Daikin Industries, Ltd., “KY-108” and “KY-164” manufactured by Shin-Etsu Chemical Co., Ltd., “Novec EGC-1720” manufactured by Sumitomo 3M Limited, and “Fluorolink S10” manufactured by Solvay Solexis, Inc.

In recent years, specific compounds each having a long-chain perfluoroalkyl group having 8 or more carbon atoms have been subject to regulations from the viewpoint of environmental protection. Accordingly, material manufacturers have started curtailing the use amounts thereof. The perfluoro(poly)ether group is not subject to such regulations and provides high water repellency, and hence has started being widely used in place of the perfluoroalkyl group. From such viewpoint, the component (B) formed of one or more kinds of hydrolyzable silane compounds each having a linear or branched perfluoro(poly)ether group is preferably used in the material for condensate formation.

However, the perfluoro(poly)ether group has had a problem of undergoing aggregation under some use conditions owing to its structural features. In particular, the aggregation often occurs during application and drying, and hence the choice of an application solvent is extremely important.

[Component (C)]

In the material for condensate formation, one kind or two or more kinds of hydrolyzable silane compounds each having an alkyl group or an aryl group may be used as a component (C) in addition to the component (A) and the component (B) given above.

The timing of adding the component (C) to the condensation reaction system is not particularly limited as long as the condensate of interest can be formed. However, from the viewpoint of effectively performing condensation with the component (A) and/or the component (B), it is preferred that the component (C) be added to the condensation reaction system concurrently with the component (A) and the component (B). The material for condensate formation containing the component (A), the component (B), and the component (C), preferably a mixture formed of the component (A), the component (B), and the component (C) may be prepared and supplied to the condensation reaction system, to thereby concurrently add the components to the condensation reaction system.

A specific example of the hydrolyzable silane compound having an alkyl group or an aryl group that may be utilized as the component (C) may be a compound represented by the following formula (13).

(R_{d})_{w}—SiX⁹_{(4-w)} Formula (13):

In the formula (13), R_{d} represents an alkyl group or an aryl group, X⁹ represents a hydrolyzable substituent, and w represents an integer of from 1 to 3.

When a plurality of w's are present, the plurality of w's each independently represent the above-mentioned meaning. When a plurality of X⁹'s are present, the plurality of X⁹'s each independently represent the above-mentioned meaning.

Examples of R_{d} include linear or branched alkyl groups each having 1 to 6 carbon atoms, such as a methyl group, an ethyl group, a propyl group, a butyl group, and a hexyl group, and a phenyl group and a naphthyl group. Specific examples of the hydrolyzable silane compound represented by the formula (13) include methyltrimethoxysilane, methyltriethoxysilane, methyltripropoxysilane, ethyltrimethoxysilane, ethyltriethoxysilane, ethyltripropoxysilane, propyltrimethoxysilane, propyltriethoxysilane, propyltripropoxysilane, dimethyldimethoxysilane, dimethyldiethoxysilane, phenyltrimethoxysilane, phenyltriethoxysilane, trimethylmethoxysilane, and trimethylethoxysilane. One kind of those hydrolyzable silane compounds each represented by the formula (13) may be used alone, or two or more kinds thereof may be used in combination.

Through the use of the component (C), preferably the hydrolyzable silane compound represented by the formula (13) in combination with the component (A) and the component (B) as the material for condensate formation, the polarity and crosslinking density of the condensate can be controlled. When such silane compound, which is not cationically polymerizable, is used in combination, the degree of freedom of a substituent, such as a perfluoro(poly)ether group or an epoxy group, improves to promote, for example, the orientation of the perfluoro(poly)ether group on an air interface side, the polymerization of the epoxy group, and the condensation of an unreacted silanol group. In addition, the presence of a non-polar group, such as an alkyl group, suppresses the cleavage of a siloxane bond to improve water repellency and durability.

[Blending Ratio of Each Component]

The blending ratio of each of the component (A) and the component (B) may be appropriately determined depending on usage patterns of the film.

From the viewpoint of providing the film with satisfactory durability and a satisfactory adhesive property for a base material surface (undercoat), the blending ratio (mol %) of the component (B) is preferably from 0.01 mol % to 10 mol % when calculated with the total number of moles of the component (A) and the component (B) being defined as 100 mol %. Further, the blending ratio of the component (B) is more preferably from 0.1 mol % to 5 mol %.

In addition, when the blending ratio of the component (B) is selected from the above-mentioned range, satisfactory water repellency can be obtained.

Further, when the blending ratio of the component (B) is selected from the above-mentioned range, its combination with a mixed solvent to be described later can further enhance the preventive effect on the aggregation of the condensate in the coating liquid.

When the three components, i.e., the component (A), the component (B), and the component (C) are used, the blending ratio of the component (A) may be selected from the viewpoint of obtaining the adhesive property for the base material surface (undercoat) and the durability of the film. From such viewpoint, the blending ratio of the component (A) is preferably from 20 mol % to 80 mol %, more preferably from 30 mol % to 70 mol % when calculated with the total number of moles of those three components being defined as 100 mol %.

[Condensation Reaction and Degree of Condensation]

In the present invention, each hydrolyzable silane compound is not used alone as a material for film formation, but the condensate obtained by performing a condensation reaction using at least the above-mentioned component (A) and component (B) is used as a material for film formation.

The condensation reaction is performed by heating the reaction system in a solvent in the presence of water to allow hydrolysis and the condensation reaction to proceed. Through appropriate control of the hydrolysis/condensation reaction based on temperature, time, concentration, pH, and the like, a condensate having a desired degree of condensation can be obtained.

A condensate of hydrolyzable silane compounds is generally synthesized in a polar organic solvent formed of a compound having a group or unit having an oxygen atom, such as a hydroxy group, a carbonyl group, or an ether bond. Specific examples of the polar organic solvent include the following polar organic solvents: alcohols, such as methanol, ethanol, propanol, isopropanol, and butanol; ketones, such as methyl ethyl ketone and methyl isobutyl ketone; esters, such as ethyl acetate and butyl acetate; ethers, such as diglyme and tetrahydrofuran; and glycols, such as diethylene glycol. One kind or a combination of two or more kinds selected from those solvents may be used.

In addition, in order to maintain the solubility of the fluorine-containing hydrolyzable silane compound, a fluorine-containing solvent, such as a hydrofluoroether (trade name: HFE7200, manufactured by Sumitomo 3M Limited), is used in combination in some cases. However, in view of the use of water in the synthesis of the condensate, alcohols having high solubility in water are most suitable. A hydrolyzable silane compound, when subjected to a reaction in an alcohol solvent, may cause a substitution reaction of a hydrolyzable substituent of the hydrolyzable silane compound to form an alkoxy group. The reactivity of a butoxy group or a propoxy group is notably low as compared to that of an ethoxy group or a methoxy group, and hence ethanol or methanol is preferred in consideration of the reactivity of an alkoxysilane compound. In addition, from the viewpoint of controlling the content of water, the heating is preferably performed at 100° C. or less. Accordingly, when the reaction is performed by heating to reflux, an alcohol having a boiling point of 100° C. or less is suitable. However, an excessively low boiling point results in a long reaction time, and hence ethanol is more suitably used than methanol.

Therefore, the synthesis of the condensate in the present invention is performed by a condensation reaction in the presence of a solvent containing at least water and ethanol. When a solvent other than water and ethanol is used, at least one kind selected from the above-mentioned polar organic solvents other than ethanol may be used.

The addition amount of the water to be used for the reaction is preferably from 0.5 equivalent to 3 equivalents, more preferably from 0.8 equivalent to 2 equivalents with respect to the total number of moles of the hydrolyzable substituents of the hydrolyzable silane compounds. When the addition amount of the water is 0.5 equivalent or more, a sufficient reaction rate in the hydrolysis/condensation reaction is obtained. In the case where a hydrolyzable silane compound having a perfluoro(poly)ether group is used, when the addition amount of the water is 3 equivalents or less, the precipitation of the hydrolyzable silane compound having a perfluoro(poly)ether group can be suppressed.

The degree to which the condensation reaction proceeds (degree of condensation) may be defined by a ratio of the number of condensed functional groups with respect to the number of condensable functional groups. The condensable functional groups correspond to the above-mentioned hydrolyzable substituents. The degree of condensation may be estimated by ²⁹Si-NMR measurement. For example, in the case of a silane compound having three hydrolyzable substituents in one molecule, the degree of condensation is calculated according to the following calculation equation (1) from the following proportions.

Degree of condensation (%)={(T1+2*T2+3*T3)*100}/{3*(T0+T1+T2+T3)} Calculation equation (1):

T0 form: Si atom not bonded to any other silane compound

T1 form: Si atom bonded to one silane compound via oxygen

T2 form: Si atom bonded to two silane compounds via oxygen

T3 form: Si atom bonded to three silane compounds via oxygen

The degree of condensation in a solution state, which also varies depending on the kinds of the hydrolyzable silane compounds to be used and synthesis conditions, is preferably 20% or more, more preferably 30% or more, still more preferably 40% or more from the viewpoints of compatibility with a resin and an application property. In addition, the degree of condensation is preferably 90% or less from the viewpoint of preventing precipitation, gelation, and the like. In this regard, however, it is rare that the degree of condensation is more than 90% under a state in which the compounds are dissolved in a solution. In addition, an increase in degree of condensation may lower the water repellency depending on composition. This is probably because the increase in degree of condensation increases the crosslinking density to lower the degree of freedom of a molecular chain, and hence the orientation of the fluorine-containing group to a coating film surface is inhibited, with the result that the fluorine-containing group density of the surface does not sufficiently increase. For example, in the case of a silane compound having a perfluoro(poly)ether group, the degree of condensation is preferably 80% or less, more preferably 70% or less. When the proportion of an unreacted silane is high, the homogeneity of the coating film lowers in some cases, and hence the proportion of the unreacted silane (T0 form) is preferably 20% or less. In addition, when the proportion of a silane in which all hydrolyzable groups are condensed increases, water-repellent and antifouling properties lower and a gel precipitates in a solution in some cases. For example, in a silane converted to a T3 form in a solution, the degree of freedom of a substituent lowers, and the surface orientation of fluorine in a coating film to be obtained is disturbed in some cases, with the result that water-repellent and antifouling properties lower in some cases. Therefore, it is preferred that the amount of the T3 form be controlled to 50% or less.

Similarly in the case of a silane compound having two hydrolyzable substituents with respect to one silane atom, the degree of condensation may be calculated according to the following calculation equation (2).

Degree of condensation (%)={(D1+2*D2)*100}/{2*(D0+D1+D2)} Calculation equation (2):

D0 form: Si atom not bonded to any other silane compound

D1 form: Si atom bonded to one silane compound via oxygen

D2 form: Si atom bonded to two silane compounds via oxygen

[Coating Liquid]

Next, the preparation of the coating liquid containing the condensate is described.

Like the solvent in the condensation reaction, a polar organic solvent formed of a compound having a group or unit having an oxygen atom, such as a hydroxy group, a carbonyl group, or an ether bond, is suitable because of high solubility of the condensate therein. Specific examples thereof include: polar organic solvents including: alcohols, such as methanol, ethanol, propanol, isopropanol, and butanol; ketones, such as methyl ethyl ketone and methyl isobutyl ketone; esters, such as ethyl acetate, butyl acetate, and propylene glycol 1-monomethyl ether 2-acetate (PGMEA); ethers, such as diglyme and tetrahydrofuran; and glycols, such as diethylene glycol and propylene glycol monomethyl ether (PGME); and fluorine-containing solvents including a hydrofluoroether. One kind or a combination of two or more kinds selected from those solvents may be used.

In the case where the surface to be treated of the base material is an uncured resin, when the coating liquid contains a solvent such as a ketone, an ester, or an ether and the uncured resin has solubility in the solvent, the following effect may be exhibited: the roughening of the base material surface; a variation in thickness of the film to be finally obtained or deformation of its shape; or the like. In such case, it is suitable to use an alcohol instead of those solvents.

However, according to investigations made by the inventors of the present invention, when an alcohol having a relatively low boiling point like ethanol was used in the synthesis of a condensate, application unevenness occurred in some cases depending on application conditions, such as the kind of the solvent contained in the coating liquid. In addition, when the evaporation rate of the solvent contained in the coating liquid was high, aggregation mainly due to the action of a fluorine-containing component occurred in some cases.

The inventors of the present invention have made extensive investigations, and as a result, have found that when ethanol is used in the synthesis of a condensate, application unevenness can be alleviated without any influence on the base material by using an alcohol having a higher boiling point than ethanol as a solvent at a specific ratio in combination with ethanol. That is, in the present invention, two kinds of alcohol components, i.e., ethanol serving as the first alcohol component, and at least one kind of alcohol having a higher boiling point than ethanol serving as the second alcohol component are incorporated into the coating liquid.

In addition, when a solvent other than an alcohol is used in the solvent in the coating liquid, at least one kind selected from the above-mentioned polar organic solvents other than an alcohol may be used.

An example of the alcohol having a higher boiling point than ethanol to be used as the second alcohol component may be an alcohol having a linear or branched alkyl group having 2 to 5 carbon atoms, and 1 or 2 hydroxy groups.

Specific examples of such alcohol specifically include: monohydric alcohols each having 3 to 5 carbon atoms, such as n-propanol, 2-propanol, n-butanol, 2-butanol, t-butanol, n-pentanol, 2-pentanol, 3-pentanol, 2-methyl-1-butanol, 3-methyl-1-butanol, 2-methyl-2-butanol, 3-methyl-2-butanol, and 2,2-dimethyl-1-propanol; and dihydric alcohols each having 2 to 4 carbon atoms, such as ethylene glycol, propylene glycol, and 1,4-butanediol.

Meanwhile, the solvent to be used as the second alcohol component in the case of using a resin material as the base material is suitably a solvent having a boiling point of 200° C. or less, more preferably a solvent having a boiling point of 150° C. or less in consideration of the heat resistance of the resin in drying by heating. Accordingly, at least one kind of 1-propanol, 2-propanol, 1-butanol, 2-butanol, t-butanol, and 2-methyl-1-propanol is preferred, and at least one kind of 1-propanol, 1-butanol, 2-butanol, and 2-methyl-1-propanol is particularly preferred. Also when a solvent other than an alcohol is contained in the solvent of the coating liquid, an organic solvent other than water having a boiling point in the above-mentioned range is preferably used.

The blending ratio of the second alcohol component to the first alcohol component is preferably from 5 parts by mass to 60 parts by mass of the second alcohol component with respect to 100 parts by mass of the first alcohol component. When the blending ratio is set to fall within the above-mentioned range, more satisfactory layer formation can be performed at the time of the drying of the applied layer.

The addition ratio of the first alcohol component to the solvent is preferably from 30 mass % to 95 mass % with respect to the total amount of the solvent contained in the coating liquid.

The addition ratio of the second alcohol component to the solvent is preferably from 2 mass % to 60 mass %, more preferably from 4 mass % to 50 mass %, most suitably from 4 mass % to 45 mass % with respect to the total amount of the solvent contained in the coating liquid.

When the ratio of the second alcohol component is small, the evaporation rate of the solvent from the coating liquid tends to be so high as to cause drying unevenness during application. When the ratio of the second alcohol component is excessively large, the film cannot express characteristics such as sufficient water repellency owing to the influence of a residual solvent in some cases. Accordingly, a blending amount need to be determined depending on the boiling point and vapor pressure of the solvent to be added, and in the present invention, the blending ratio of the second alcohol component is selected from the above-mentioned range.

For example, when the film according to the present invention is applied as a water-repellent and antifouling film in a liquid ejection head according to one embodiment of the present invention, a variation in water repellency due to drying unevenness or lowering of water repellency due to insufficient drying occurs in some cases. In such cases, a site where the liquid is difficult to remove is generated during wiping of the surface of the liquid ejection head in which an ejection orifice is formed, and sticking of a solid content precipitated from the liquid occurs at the site. Sticking of the solid content in the vicinity of the ejection orifice may cause clogging of the ejection orifice or a liquid ejection failure, and hence the present invention may be said to be means extremely effective for achieving the improvement of printing quality.

The preparation of the coating liquid may be performed through a step of dissolving the condensate in a solvent.

The condensate may be used in the preparation of the coating liquid in a state of being contained in a liquid condensation reaction product obtained by the condensation reaction in the presence of water and ethanol using the material for condensate formation containing at least the component (A) and the component (B), and further containing the component (C) as necessary. The liquid condensation reaction product in this case is a liquid composition containing the condensate, an unreacted material for condensate formation, water, and ethanol. The kind and amount of the unreacted material for condensate formation vary depending on the degree of condensation. When the component (A) and component (B) are used as the material for condensate formation and when not the whole amounts of these components are condensed, at least one of the components is left in an unreacted state in the condensation reaction product. The same applies to the case where the component (C) is used.

When the condensate is used in the preparation of the coating liquid in a state of the above-mentioned liquid condensation reaction product, the coating liquid may be obtained by diluting the condensation reaction product with a diluting solvent. As the diluting solvent to be used in such case, at least one kind of the first alcohol component and the second alcohol component may be used. The coating liquid may be obtained by adjusting the amount of the diluting solvent so that the amount of the second alcohol component with respect to the total amount of the solvent contained in the coating liquid falls within the specific ratio range given above (2.00 mass % to 60.00 mass %).

Although a condensate obtained through separation and/or purification from the condensation reaction product may be used in the preparation of the coating liquid, when the condensation reaction product containing the condensate, an unreacted material for condensate formation, and the solvent is used as it is in the preparation of the coating liquid, the simplification of the process and a reduction in manufacturing cost can be achieved.

As described above, the degree of condensation of the condensate in the condensation reaction product is preferably from 20% to 80%.

The blending ratio of the condensate in the coating liquid is not particularly limited, and may be selected depending on the intended use and characteristics of the film to be formed using the coating liquid. When the film is used for an ink jet recording head, the concentration of the condensate in the coating liquid is preferably selected from the range of from 0.1 mass % to 30 mass % from the viewpoints of an application property and water repellency.

[Manufacture of Film]

Through curing of the applied layer obtained by applying the coating liquid onto the surface of the base material to be subjected to surface treatment, the film containing the condensate can be manufactured on the base material. As the base material, a portion constituting at least part of a member to be subjected to surface treatment of any of various products may be used.

The curing treatment of the applied layer may be performed mainly by utilizing the epoxy group of the condensate contained in the coating liquid, and may be performed by light irradiation and/or heating treatment in accordance with a routine procedure.

Now, a mode involving: using, as the base material, a base material in which at least a surface to be treated is formed of a curable resin composition in an uncured state; and simultaneously curing the uncured resin constituting the surface to be treated of the base material and the condensate is described.

As the curable resin composition to be used in the formation of at least the surface to be treated of the base material, there may be used a negative-type epoxy resin composition containing as a main agent a polyfunctional epoxy resin, such as a bisphenol A-type epoxy resin, a bisphenol E-type epoxy resin, a bisphenol F-type epoxy resin, a novolac-type epoxy resin, a cresol novolac-type epoxy resin, or an alicyclic epoxy resin. Commercial products of the epoxy resin are, for example, “157S70” and “jER 1031S” (trade names) manufactured by Mitsubishi Chemical Corporation, “EPICLON N-695” and “EPICLON N-865” (trade names) manufactured by Dainippon Ink and Chemicals, Incorporated, “CELLOXIDE 2021”, “GT-300 series”, “GT-400 series”, and “EHPE3150” (trade names) manufactured by Daicel Corporation, “SU8” (trade name) manufactured by Nippon Kayaku Co., Ltd., “VG3101” (trade name) and “EPDX-MKR1710” (trade names) manufactured by Printec Co., Ltd., and “Denacol series” manufactured by Nagase ChemteX Corporation.

The base material may have such structure that the entire base material is formed of the curable resin composition, or may have such structure that a layer of the curable resin composition is formed on the base material to serve as the surface to be treated.

When the coating liquid is applied onto the surface to be treated of the base material, the combination of the solvent and the base material surface-forming material contained in the coating liquid is extremely important. When a material having high solubility in an alcohol solvent is used for the formation of the base material surface, it becomes difficult to control a pattern shape in the vicinity of an interface between the applied layer and the base material surface, with the result that a desired shape cannot be achieved in some cases. Accordingly, when the main component of the solvent contained in the coating liquid is an alcohol solvent, a bisphenol-type epoxy resin and a novolac-type epoxy resin, each of which has relatively low solubility in the alcohol solvent, is suitable.

A photopolymerization initiator may be added to the curable resin composition to be used for the formation of the surface to be treated of the base material. The photopolymerization initiator is preferably a sulfonic acid compound, a diazomethane compound, a sulfonium salt compound, an iodonium salt compound, a disulfone-based compound, or the like. Commercial products thereof are, for example, “ADEKA OPTOMER SP-170”, “ADEKA OPTOMER SP-172”, and “ADEKA OPTOMER SP-150” (trade names) manufactured by ADEKA Corporation, “BBI-103” and “BBI-102” (trade names) manufactured by Midori Kagaku Co., Ltd., “IBPF”, “IBCF”, “TS-01”, and “TS-91” (trade names) manufactured by Sanwa Chemical Industrial Co., Ltd., and “CPI-410” (trade name, manufactured by San-Apro Ltd.). The epoxy resin composition may further contain, for example, a basic substance, such as an amine, a photosensitizing substance, such as an anthracene derivative, or a silane coupling agent, for the purpose of improving photolithography performance, adhesion performance, or the like.

The photocurable epoxy resin containing the epoxy resin and the photopolymerization initiator given above may be used for the formation of the surface to be treated of the base material.

The addition ratio of the photopolymerization initiator in the case of using the photocurable epoxy resin for the formation of the surface to be treated of the base material is preferably 40 mass % or less within a range in which photopolymerization of interest is achieved and from the viewpoint of an application property.

The condensate according to the present invention may be cured through exposure and heating treatment with the actions of the photopolymerization initiator and the epoxy resin contained in the base material as disclosed in Japanese Patent Application Laid-Open No. 2007-518587.

However, in the case of a mode in which a bisphenol-type epoxy resin or a novolac-type epoxy resin is used for the formation of the surface to be treated of the base material to suppress mutual dissolution with the condensate, it is preferred that a photopolymerization initiator and an epoxy resin be added to the coating liquid as well. When the photopolymerization initiator and/or the photocurable epoxy resin are added to both the base material side and the applied layer side as just described, energy required for the curing of the curable resin composition in an uncured state on the applied layer and base material sides can be decreased in some cases. This results in extreme usefulness for the improvement of film characteristics such as water repellency and the improvement of a patterning property.

As the photopolymerization initiator and/or the epoxy resin to be added to the coating liquid, at least one kind of those exemplified above for use in the base material may be used. The epoxy resin is preferably a polyfunctional alicyclic epoxy resin, such as “EHPE3150” (trade name).

When the photopolymerization initiator is added to the coating liquid, the blending ratio of the photopolymerization initiator is preferably from 0.1 mass % to 20.0 mass % with respect to the entirety of the coating liquid from the viewpoints of solubility in the application solvent and the curability of the water-repellent and antifouling film.

The material and shape of the base material on which the film according to the present invention is to be formed are not particularly limited as long as the base material can be utilized as an object of surface treatment by the formation of the film. The surfaces (including an outer surface and an inner surface) of various products may each serve as the base material.

As an example in which the manufacturing method for a film according to the present invention may be applied, a manufacturing method for an ink jet recording head in which the film is utilized as a water-repellent and antifouling film is described below. The application range of the manufacturing method for a film according to the present invention is not limited thereto.

[Water-repellent and Antifouling Treatment of Ink Jet Recording Head]

A manufacturing method for a water-repellent and antifouling film according to the present invention may be applied to a water-repellent and antifouling treatment method for the surface of a liquid ejection head in which an ejection orifice is formed, and further, to a manufacturing method for a liquid ejection head involving using such water-repellent and antifouling treatment method.

As an example in which the manufacturing method for a water-repellent and antifouling film according to the present invention may be applied, a manufacturing method for an ink jet recording head serving as one mode of a liquid ejection head is described below. The application range of the manufacturing method for a water-repellent and antifouling film according to the present invention is not limited thereto.

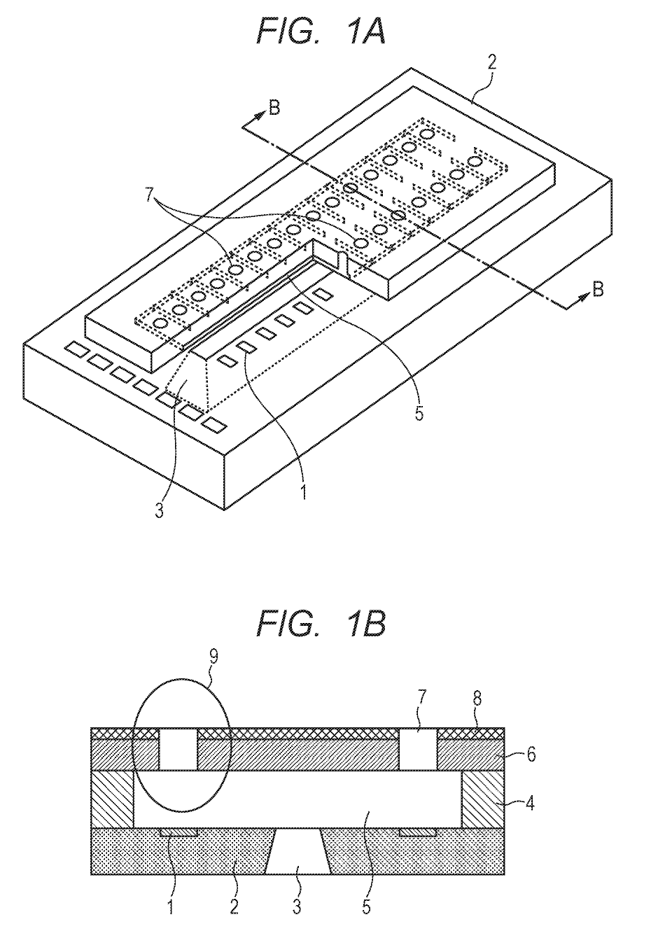

FIG. 1A is a schematic perspective view for illustrating an example of an ink jet recording head obtained by applying the manufacturing method for a water-repellent and antifouling film according to this embodiment. In addition, FIG. 1B is a schematic cross-sectional view for illustrating a cross-section of the ink jet recording head taken along the line B-B of FIG. 1A.

The ink jet recording head illustrated in FIG. 1A and FIG. 1B includes a substrate 2 on which energy generating elements 1 configured to generate energy to be utilized for ejecting ink are arranged at a predetermined pitch. In the substrate 2, a supply portion 3 configured to supply ink is opened between two rows of the energy generating elements 1. On the substrate 2, a flow path 5 for ink is formed by a flow path-forming member 4. In addition, ejection orifices 7 are formed in an ejection orifice-forming member 6, which corresponds to the base material serving as the object of the water-repellent and antifouling treatment in the method according to the present invention.

The flow path-forming member 4 and the ejection orifice-forming member 6 may be an integral body.

On the surface of the ejection orifice-forming member 6 in which the ejection orifices 7 are open, there is formed a water-repellent layer 8, which corresponds to the water-repellent and antifouling film obtained by the method according to the present invention.

In the ink jet recording head illustrated in FIG. 1A and FIG. 1B, energy generated by the energy generating elements 1 is applied to the ink supplied from the supply portion 3 via the flow path 5, and thus the ink is ejected as a liquid droplet via each of the ejection orifices 7.

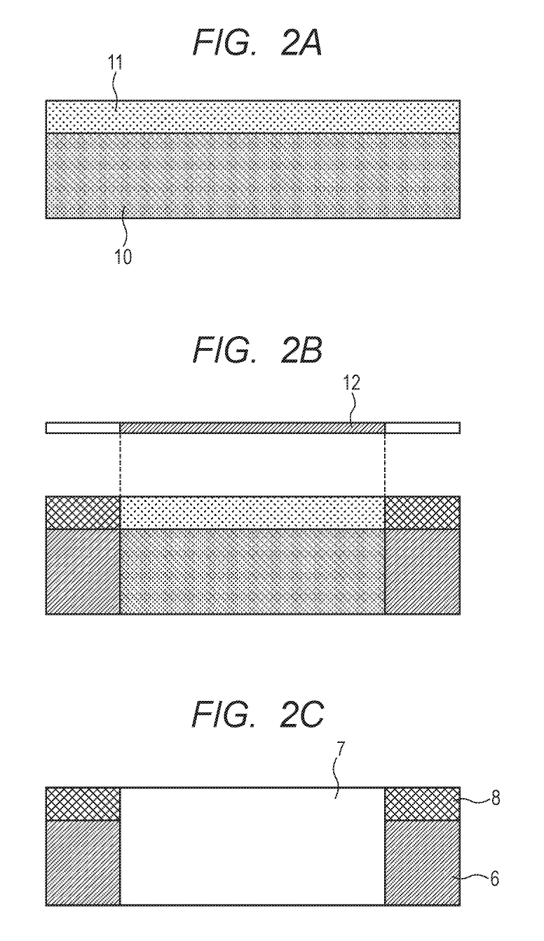

FIG. 2A to FIG. 2C are schematic cross-sectional views for illustrating an example of a manufacturing method for an ink jet recording head in which the manufacturing method for a water-repellent and antifouling film in this embodiment is applied. In FIG. 2A to FIG. 2C, an ejection portion 9 of FIG. 1B is enlarged and illustrated for each step.

First, onto a resin layer 10 in an uncured state formed of a curable resin composition, the coating liquid according to the present invention is applied, and dried by heat treatment to provide an applied layer 11 (FIG. 2A). Next, the resin layer 10 and the applied layer 11 are simultaneously pattern-exposed via a mask 12 having an ejection orifice pattern, and are further subjected to heat treatment to cure their exposed portions (FIG. 2B). The mask 12 is obtained by forming a light-shielding film, such as a chromium film, in accordance with a pattern, such as ejection orifices, on the substrate 2 made of a material, such as glass or quartz, transmitting light having an exposure wavelength. As an exposing apparatus, a projection exposing apparatus including a light source having a single wavelength, such as an i-line exposure stepper or a KrF stepper, or a light source having a broad wavelength of a mercury lamp, such as a mask aligner MPA-600 Super (trade name, manufactured by Canon Inc.), may be used.

Next, uncured portions of the resin layer 10 and the applied layer 11 are removed with an organic solvent to form the ejection orifice-forming member 6, the ejection orifice 7, and the water-repellent layer 8 (FIG. 2C).

Through the steps described above, a water-repellent and antifouling film improved in water repellency and durability can be more uniformly formed on the surface of the ejection orifice-forming member 6 in which the ejection orifice 7 is open, including a region at an open end of the ejection orifice 7.

Now, the present invention is further described in detail by way of Examples of the present invention.

### SYNTHESIS EXAMPLE 1

A condensate (i) formed of hydrolyzable silane compounds was prepared by the following procedure.

Components shown in Table 1 were loaded into a flask with a condenser, and were stirred at room temperature for 5 minutes. After that, the mixture was heated to reflux for 33 hours to provide the condensate (i). In this case, a theoretical solid content concentration calculated on the assumption that all hydrolyzable groups of the hydrolyzable silane compounds have been subjected to hydrolysis/condensation is 26.5%. ²⁹Si-NMR was measured and the degree of condensation was calculated to be 55%.

### SYNTHESIS EXAMPLE 2

A condensate (ii) formed of hydrolyzable silane compounds was prepared by the following procedure.

Components shown in Table 1 were loaded into a flask with a condenser, and were stirred at room temperature for 5 minutes. After that, the mixture was heated to reflux for 24 hours to provide the condensate (ii). In this case, a theoretical solid content concentration calculated on the assumption that all hydrolyzable groups of the hydrolyzable silane compounds have been subjected to hydrolysis/condensation is 26.5%. ²⁹Si-NMR was measured and the degree of condensation was calculated to be 17%.

### SYNTHESIS EXAMPLE 3

A condensate (iii) formed of hydrolyzable silane compounds was prepared by the following procedure.

Components shown in Table 1 were loaded into a flask with a condenser, and were stirred at room temperature for 5 minutes. After that, the mixture was heated to reflux for 30 hours to provide the condensate (iii). In this case, a theoretical solid content concentration calculated on the assumption that all hydrolyzable groups of the hydrolyzable silane compounds have been subjected to hydrolysis/condensation is 26.5%. ²⁹Si-NMR was measured and the degree of condensation was calculated to be 20%.

### SYNTHESIS EXAMPLE 4

A condensate (iv) formed of hydrolyzable silane compounds was prepared by the following procedure.

Components shown in Table 1 were loaded into a flask with a condenser, and were stirred at room temperature for 5 minutes. After that, the mixture was heated to reflux for 80 hours to provide the condensate (iv). In this case, a theoretical solid content concentration calculated on the assumption that all hydrolyzable groups of the hydrolyzable silane compounds have been subjected to hydrolysis/condensation is 26.5%. ²⁹Si-NMR was measured and the degree of condensation was calculated to be 70%.

### SYNTHESIS EXAMPLE 5

A condensate (v) formed of hydrolyzable silane compounds was prepared by the following procedure.

Components shown in Table 1 were loaded into a flask with a condenser, and were stirred at room temperature for 5 minutes.

After that, the mixture was heated to reflux for 24 hours to provide the condensate (v). In this case, a theoretical solid content concentration calculated on the assumption that all hydrolyzable groups of the hydrolyzable silane compounds have been subjected to hydrolysis/condensation is 28%. ²⁹Si-NMR was measured and the degree of condensation was calculated to be 70%.

### SYNTHESIS EXAMPLE 6

A condensate (vi) formed of hydrolyzable silane compounds was prepared by the following procedure.

Components shown in Table 1 were loaded into a flask with a condenser, and were stirred at room temperature for 5 minutes. After that, the mixture was heated to reflux for 72 hours to provide the condensate (vi). In this case, a theoretical solid content concentration calculated on the assumption that all hydrolyzable groups of the hydrolyzable silane compounds have been subjected to hydrolysis/condensation is 28%. ²⁹Si-NMR was measured and the degree of condensation was calculated to be 86%.

### SYNTHESIS EXAMPLE 7

A condensate (vii) formed of hydrolyzable silane compounds was prepared by the following procedure.

Components shown in Table 1 were loaded into a flask with a condenser, and were stirred at room temperature for 5 minutes to provide the condensate (vii).

### SYNTHESIS EXAMPLE 8

A condensate (viii) formed of hydrolyzable silane compounds was prepared by the following procedure.

Components shown in Table 1 were loaded into a flask with a condenser, and were stirred at room temperature for 5 minutes. Next, the mixture was subjected to reflux for 48 hours to provide the condensate (viii). In this case, a theoretical solid content concentration calculated on the assumption that all hydrolyzable groups of the hydrolyzable silane compounds have been subjected to hydrolysis/condensation is 28%. ²⁹Si-NMR was measured and the degree of condensation was calculated to be 80%.

TABLE 1

| | Synthesis | Synthesis | Synthesis | Synthesis | Synthesis | Synthesis | Synthesis | Synthesis |
|---|---|---|---|---|---|---|---|---|
| | Example 1 | Example 2 | Example 3 | Example 4 | Example 5 | Example 6 | Example 7 | Example 8 |
| Condensate | (i) | (ii) | (iii) | (iv) | (v) | (vi) | (vii) | (viii) |
| γ-Glycidoxypropyl- | 13.81 g | 13.81 g | 13.81 g | 13.81 g | 27.84 g | 27.84 g | 27.84 g | 27.84 g |
| triethoxysilane | (0.0496 | (0.0496 | (0.0496 | (0.0496 | (0.1000 | (0.1000 | (0.1000 | (0.1000 |
| | mol) | mol) | mol) | mol) | mol) | mol) | mol) | mol) |
| Compound | 1.05 g | 1.05 g | 1.05 g | 1.05 g | — | — | — | — |
| represented by | (0.0008 | (0.0008 | (0.0008 | (0.0008 | | | | |
| formula (14) | mol) | mol) | mol) | mol) | | | | |
| Tridecafluoro-1,1,2,2- | — | — | — | — | 6.64 g | 6.64 g | — | — |
| tetrahydrooctyl- | | | | | (0.0130 | (0.0130 | | |
| triethoxysilane | | | | | mol) | mol) | | |
| Perfluorodecylethyl- | — | — | — | — | — | — | 3.35 g | 3.35 g |
| triethoxysilane | | | | | | | (0.0047 | (0.0047 |
| | | | | | | | mol) | mol) |
| Methyltriethoxysilane | 4.42 g | 4.42 g | 4.42 g | 4.42 g | 17.83 g | 17.83 g | 17.83 g | 17.83 g |
| | (0.0248 | (0.0248 | (0.0248 | (0.0248 | (0.1000 | (0.1000 | (0.1000 | (0.1000 |
| | mol) | mol) | mol) | mol) | mol) | mol) | mol) | mol) |
| Phenyltrimethoxysilane | 5.96 g | 5.96 g | 5.96 g | 5.96 g | — | — | — | — |
| | (0.0248 | (0.0248 | (0.0248 | (0.0248 | | | | |
| | mol) | mol) | mol) | mol) | | | | |
| Water | 6.54 g | 4.36 g | 4.36 g | 6.54 g | 17.25 g | 17.25 g | — | 16.58 g |
| Ethanol | 19.06 g | 21.24 g | 21.24 g | 19.06 g | 32.65 g | 32.65 g | 37 g | 30.05 g |
| Hydrofluoroether | 4.22 g | 4.22 g | 4.22 g | 4.22 g | — | — | — | — |

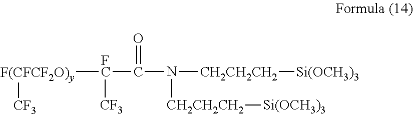

In the formula (14), y represents an integer of from 4 to 6.

### EXAMPLE 1

An ejection orifice-forming member and the like of an ink jet recording head were produced in a simplified manner on a silicon substrate through the steps illustrated in FIG. 2A to FIG. 2C.

First, a curable epoxy resin composition having composition shown in Table 2 was applied to form the resin layer 10 in an uncured state.

TABLE 2

| | | |
|---|---|---|
| Epoxy resin | Trade name: 157S70, | 100 parts by mass |
| | manufactured by Mitsubishi | |
| | Chemical Corporation | |
| Photo- | Trade name: CPI-410, | 0.01 part by mass |
| polymerization | manufactured by San-Apro Ltd. | |
| initiator | | |
| Solvent | PGMEA, manufactured by | 20 parts by mass |
| | Kishida Chemical Co., Ltd. | |

Onto the resin layer 10, a coating liquid having composition shown in Example 1 of Table 4-1 was applied by a spin coating method so that a coating film after drying had a thickness of 1.0 μm, and the resultant was subjected to heat treatment at 50° C. for 5 minutes to form the applied layer 11. Thus, as illustrated in FIG. 2A, the applied layer 11 was formed on the resin layer 10.

Subsequently, as illustrated in FIG. 2B, the resin layer 10 and the applied layer 11 were simultaneously pattern-exposed via the mask 12 having a pattern of ejection orifices. An i-line exposure stepper (manufactured by Canon Inc.) was used as an exposing machine. The amount of exposure was set to 1,100 J/m². After that, heat treatment was further performed to cure the exposed portions.

After that, as illustrated in FIG. 2C, PGMEA was used to dissolve and remove uncured portions of the resin layer 10 and the applied layer 11, to form the ejection orifice-forming member 6, the ejection orifices 7, and the water-repellent layer 8.

### EXAMPLES 4, 5, AND 14 TO 16

The ejection orifice-forming member 6, the ejection orifices 7, and the water-repellent layer 8 were formed in the same manner as in Example 1 except that coating liquids having compositions shown in Examples 4, 5, and 14 to 16 of Table 4-1 and Table 4-2 were respectively used in the formation of the applied layer 11.

### EXAMPLES 2, 3, AND 6 TO 13

The ejection orifice-forming member 6, the ejection orifices 7, and the water-repellent layer 8 were formed in the same manner as in Example 1 except that: an epoxy resin composition having composition shown in Table 3 was used in the formation of the resin layer 10; and coating liquids having compositions shown in Examples 2, 3, and 6 to 13 of Table 4-1 and Table 4-2 were respectively used in the formation of the applied layer 11.

TABLE 3

| | | |
|---|---|---|
| Epoxy resin | Trade name: EHPE-3150, | 100 parts by mass |
| | manufactured by Daicel | |
| | Corporation | |
| Photo- | Trade name: ADEKA OPTOMER | 6 parts by mass |
| polymerization | SP-172, manufactured by | |
| initiator | ADEKA Corporation | |
| Solvent | Xylene, manufactured by | 70 parts by mass |
| | Kishida Chemical Co., Ltd. | |

### EXAMPLE 17

The ejection orifice-forming member 6, the ejection orifices 7, and the water-repellent layer 8 were formed in the same manner as in Example 1, and any other member was produced by using a known manufacturing method to provide the ink jet recording head illustrated in FIG. 1B.

### COMPARATIVE EXAMPLES 1 TO 6

The ejection orifice-forming member 6, the ejection orifices 7, and the water-repellent layer 8 were formed in the same manner as in Example 1 except that: an epoxy resin composition having composition shown in Table 3 was used in the formation of the resin layer 10; and coating liquids having compositions shown in Comparative Examples 1 to 6 of Table 4-2 were respectively used in the formation of the applied layer 11.

[Evaluation Methods]

### (Application Property)

The laminated structure of the resin layer after curing and the water-repellent layer on the resin layer produced by each of the methods of Examples 1 to 16, and Comparative Examples 1 to 6 was subjected to external appearance observation visually and with an optical microscope, and an application property was evaluated based on the following criteria.
++: No external appearance unevenness is found in visual observation and optical microscope observation.
+: No external appearance unevenness is found in visual observation, but unevenness is found in optical microscope observation.
±: Partial external appearance unevenness is found in visual observation.
−: External appearance unevenness is found over the entire surface in visual observation.

(Water Repellency)

The water-repellent layer 8 was measured for a dynamic receding contact angle θr with pure water through the use of a micro contact angle meter (product name: DropMeasure, manufactured by Microjet Corporation), and water repellency was evaluated based on the following criteria.
++: 95° or more
+: 80° or more and less than 95°
±: 70° or more and less than 80°
−: Less than 70°

(Ink Sticking after Wiping)

While pigment ink was sprayed onto the surface of the water-repellent layer 8, a wiping operation using a blade made of hydrogenated nitrile rubber (HNBR) was carried out, and the presence or absence of sticking of the ink onto the surface of the laminate after 2,000 times of wiping and after 5,000 times of wiping was confirmed using an optical microscope. The evaluation criteria for the application property and the water repellency are as described below.

The results of the above-mentioned evaluations are shown in Table 4-1 and Table 4-2.

Further, for the liquid ejection head produced by the method of Example 17, printing quality after 5,000 times of wiping was evaluated. The pattern of printing utilized was such that the success or failure of the ejection of ink from each ejection orifice, slippage, and the like were able to be observed.

TABLE 4-1

| | | | Example | | | | | | | | | | |
|---|---|---|---|---|---|---|---|---|---|---|---|---|---|
| | | | 1 | 2 | 3 | 4 | 5 | 6 | 7 | 8 | 9 | 10 | 11 |
| Condensate | | | (i) | (i) | (i) | (i) | (i) | (i) | (i) | (i) | (i) | (viii) | (iv) |
| Degree of condensation | | | 55% | 55% | 55% | 55% | 55% | 55% | 55% | 55% | 55% | 80% | 70% |
| Composition of | Amount of condensate | | 1.03 | 7.00 | 7.00 | 1.03 | 1.03 | 7.00 | 7.00 | 7.00 | 7.00 | 7.00 | 7.00 |
| coating liquid | in terms of solid content | | | | | | | | | | | | |
| (part(s) | First | EtOH | 75.29 | 79.05 | 91.00 | 84.14 | 44.29 | 33.00 | 79.05 | 79.05 | 79.05 | 79.05 | 79.05 |
| by mass) | alcohol | | | | | | | | | | | | |
| | component | | | | | | | | | | | | |
| | Second | n-PrOH | | | | | | | 13.95 | | | | |
| | alcohol | 2-PrOH | | | | | | | | | | | |
| | component | n-BtOH | | | | | | | | | 13.95 | | |
| | or other | 2-BtOH | 13.29 | 13.95 | 2.00 | 4.43 | 44.29 | 60.00 | | | | 13.95 | 13.95 |
| | solvent | 2-Met-1- | | | | | | | | 13.95 | | | |
| | component | PrOH | | | | | | | | | | | |
| | | PGMEA | 4.43 | | | 4.43 | 4.43 | | | | | | |
| | | 1,4-BG | | | | | | | | | | | |
| | Polyfunc- | EHPE- | 5.86 | | | 5.86 | 5.86 | | | | | | |
| | tional | 3150 | | | | | | | | | | | |
| | alicyclic | (trade | | | | | | | | | | | |
| | epoxy resin | name) | | | | | | | | | | | |
| | Initiator | CPI-410 | 0.10 | | | 0.10 | 0.10 | | | | | | |
| | Total | | 100.00 | 100.00 | 100.00 | 99.99 | 100.00 | 100.00 | 100.00 | 100.00 | 100.00 | 100.00 | 100.00 |
| Solid content concentration of | | | 6.99 | 7.00 | 7.00 | 6.99 | 6.99 | 7.00 | 7.00 | 7.00 | 7.00 | 7.00 | 7.00 |
| coating liquid (%) | | | | | | | | | | | | | |
| Composition of base material- | | | Table 2 | Table 3 | Table 3 | Table 2 | Table 2 | Table 3 | Table 3 | Table 3 | Table 3 | Table 3 | Table 3 |
| side resin layer | | | | | | | | | | | | | |
| Evaluation | Application property | | ++ | ++ | + | ++ | ++ | ++ | ++ | ++ | ++ | ++ | ++ |
| item | Water repellency | | ++ | ++ | ++ | ++ | ++ | + | ++ | ++ | ++ | + | + |
| | Ink | 2,000 | Absent | Absent | Present | Absent | Absent | Present | Absent | Absent | Absent | Absent | Absent |
| | sticking | times | | | | | | | | | | | |
| | after | 5,000 | Absent | Present | Present | Absent | Absent | Present | Present | Present | Present | Present | Present |
| | wiping | times | | | | | | | | | | | |

TABLE 4-2

| | | | Example | | | | | Comparative Example | | | | | |
|---|---|---|---|---|---|---|---|---|---|---|---|---|---|
| | | | 12 | 13 | 14 | 15 | 16 | 1 | 2 | 3 | 4 | 5 | 6 |
| Condensate | | | (vi) | (ii) | (iii) | (i) | (i) | (viii) | (vii) | (i) | (v) | (i) | (v) |
| Degree of condensation | | | 86% | 17% | 20% | 55% | 55% | 80% | 0% | 55% | 70% | 55% | 70% |
| Composition of | Amount of condensate | | 7.00 | 7.00 | 1.03 | 1.03 | 7.00 | 7.00 | 7.00 | 7.00 | 7.00 | 7.00 | 7.00 |
| coating liquid | in terms of solid content | | | | | | | | | | | | |
| (part(s) | First | EtOH | 79.05 | 79.05 | 79.29 | 79.14 | 74.54 | 93.00 | 93.00 | 92.00 | 13.00 | 79.05 | 79.05 |
| by mass) | alcohol | | | | | | | | | | | | |
| | component | | | | | | | | | | | | |
| | Second | n-PrOH | | | | | | | | | | | |
| | alcohol | 2-PrOH | | | | | | | | | | 13.95 | |
| | component | n-BtOH | | | | | | | | | | | |
| | or other | 2-BtOH | 13.95 | 13.95 | 13.29 | 13.97 | 13.93 | | | 1.00 | 80.00 | | |
| | solvent | 2-Met-1- | | | | | | | | | | | |
| | component | PrOH | | | | | | | | | | | |
| | | PGMEA | | | 4.43 | | 4.43 | | | | | | |
| | | 1,4-BG | | | | | | | | | | | 13.95 |
| | Polyfunc- | EHPE- | | | 5.86 | 5.86 | | | | | | | |
| | tional | 3150 | | | | | | | | | | | |
| | alicyclic | (trade | | | | | | | | | | | |
| | epoxy resin | name ) | | | | | | | | | | | |
| | Initiator | CPI-410 | | | 0.10 | | 0.10 | | | | | | |
| | Total | | 100.00 | 100.00 | 100.00 | 100.00 | 100.00 | 100.00 | 100.00 | 100.00 | 100.00 | 100.00 | 100.00 |
| Solid content concentration of | | | 7.00 | 7.00 | 6.99 | 6.89 | 7.10 | 7.00 | 7.00 | 7.00 | 7.00 | 7.00 | 7.00 |
| coating liquid (%) | | | | | | | | | | | | | |
| Composition of base material- | | | Table 3 | Table 3 | Table 2 | Table 2 | Table 2 | Table 3 | Table 3 | Table 3 | Table 3 | Table 3 | Table 3 |
| side resin layer | | | | | | | | | | | | | |
| Evaluation | Application property | | ++ | + | ++ | ++ | ++ | − | − | ± | ± | − | + |
| item | Water repellency | | + | + | ++ | ++ | ++ | ± | − | ± | ± | ± | − |
| | Ink | 2,000 | Absent | Absent | Absent | Absent | Absent | Present | Present | Present | Present | Present | Present |
| | sticking | times | | | | | | | | | | | |
| | after | 5,000 | Present | Present | Absent | Present | Present | Present | Present | Present | Present | Present | Present |
| | wiping | times | | | | | | | | | | | |

Abbreviations of the alcohol components in Table 4-1 and Table 4-2 represent the following compound names, and their respective boiling points are also shown below.
EtOH: ethanol (boiling point: 78.3° C.)
n-PrOH: n-propanol (boiling point: 97° C.)
2-PrOH: n-propanol (boiling point: 82° C.)
n-BtOH: n-butanol (boiling point: 117° C.)
2-BtOH: 2-butanol (boiling point: 99° C.)
2-Met-l-PrOH: 2-methyl-1-propanol (boiling point: 108° C.)
PGMEA: propylene glycol 1-monomethyl ether 2-acetate (boiling point: 146° C.)
1,4-BG: 1,4-butanediol (boiling point: 230° C.)

As shown in Table 4-1 and Table 4-2, the method according to each of Examples of the present invention was able to achieve the formation of a uniform film, and the expression of water repellency. In particular, in each of Examples 1, 2, 4, 5, and 7 to 16, in which 4 parts by mass to 45 parts by mass of the second alcohol component was added, sticking of ink onto the surface of the laminated structure was not found even after 2,000 times of wiping, and thus it was able to be demonstrated that the present invention was extremely effective means when applied to an ink jet recording head.

Further, in Examples 1, 4, 5, and 14, the epoxy resin composition having the composition shown in Table 2 was used in the formation of the resin layer 10, and respective compositions obtained by adding a resin and an initiator to the condensate serving as a water-repellent component were used in the formation of the applied layer 11. In each of those Examples, extremely high water repellency was obtained, and sticking of ink did not occur even after 5,000 times of wiping.

In Example 3, the evaluation of ink sticking after 2,000 times of wiping was “Present”, but the sticking was only slightly found at such a level as not to cause a problem in practical use.

In the evaluation performed for the liquid ejection head produced in Example 17, even after wiping, printing slippage or ejection failure was not found, and thus satisfactory printing quality was obtained.

Meanwhile, in each of the methods according to Comparative Examples, in particular, Comparative Examples 1, 2, 5, and 6, uniform film formation or the expression of uniform water repellency was unable to be achieved. In Comparative Example 3, the addition amount of the second alcohol component was insufficient, resulting in drying unevenness.

In addition, in Comparative Example 4, lowering of the application property and the water repellency due to the influence of the residual solvent occurred owing to the excessively large addition amount.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2016-037874, filed Feb. 29, 2016, which is hereby incorporated by reference herein in its entirety.

What is claimed is:

1. A manufacturing method for a film containing a condensate of hydrolyzable silane compounds, the manufacturing method comprising:
forming, on a base material, a layer containing a condensate of a hydrolyzable silane compound having an epoxy group and a hydrolyzable silane compound having a fluorine-containing group, and a solvent; and
curing the layer,
the solvent containing one of ethanol and methanol serving as a first alcohol component, and at least one kind of alcohol having a boiling point of from 90° C. to 200° C. serving as a second alcohol component, the solvent having a content of the second alcohol component of from 2.00 mass % to 60.00 mass %,
the condensate having a degree of condensation of from 20% to 80%.

2. A manufacturing method according to claim 1, wherein the first alcohol component comprises ethanol.

3. A manufacturing method according to claim 1, wherein the second alcohol component comprises at least one kind selected from n-propanol, n-butanol, 2-butanol, and 2-methyl-1-propanol.

4. A manufacturing method according to claim 1, wherein the second alcohol component comprises 2-butanol.

5. A manufacturing method according to claim 1, wherein the hydrolyzable silane compound having a fluorine-containing group comprises a hydrolyzable silane compound having a perfluoro(poly)ether group.

6. A manufacturing method according to claim 5, wherein the hydrolyzable silane compound having a perfluoro(poly)ether group comprises at least one kind of compounds represented by the following formulae (3) to (6):
F—Rₚ¹-A¹-SiX⁴_{c}Y¹_{(3-c)} Formula (3):
R³_{(3-d)}X⁵_{d}Si-A²-Rₚ²-A³-AiX⁶ₑY²₍₃₋ₑ₎ Formula (4): 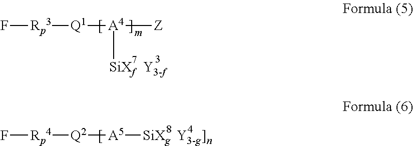
in the formulae (3) to (6):
Rₚ¹ to Rₚ⁴ each independently represent a perfluoro(poly)ether group represented by the following formula (7), A¹ to A⁵ each independently represent an organic bonding group having 1 to 12 carbon atoms, X⁴ to X⁸ each independently represent a hydrolyzable substituent, and Y¹ to Y⁴ and R³ each independently represent a non-hydrolyzable substituent;
Z represents a hydrogen atom or an alkyl group, Q¹ and Q² each independently represent a divalent or trivalent bonding group, provided that when Q² is divalent, n=1, and that when Q² is trivalent, n=2, a to g each independently represent an integer of from 1 to 3, and m represents an integer of from 1 to 4; and
units represented by -[A⁴(SiX⁷_{f}Y³_{(3-f)})]— when n represents 2 each independently have the above-mentioned meaning, and units represented by -A⁵-SiX⁵_{g}Y⁴_{(3-g)} when m represents from 2 to 4 each independently have the above-mentioned meaning: 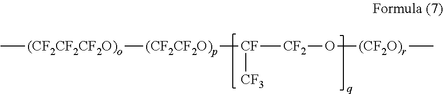
in the formula (7), o, p, q, and r each independently represent an integer of 0 or 1 or more, and at least one of o, p, q, and r represents an integer of 1 or more.

7. A manufacturing method according to claim 1, wherein the curing the layer is performed by exposure and heating treatment.

8. A manufacturing method according to claim 1, wherein a surface of the base material on which the layer is to be formed comprises a resin layer in an uncured state containing a photocurable epoxy resin and a photopolymerization initiator.

9. A manufacturing method according to claim 8, wherein the photocurable epoxy resin comprises one of a novolac-type epoxy resin and a bisphenol A-type epoxy resin.

10. A manufacturing method according to claim 1, wherein the layer contains a photocurable epoxy resin and a photopolymerization initiator.

11. A manufacturing method according to claim 8, wherein the layer contains a photocurable epoxy resin and a photopolymerization initiator.

12. A manufacturing method according to claim 10, wherein the photocurable epoxy resin comprises a polyfunctional alicyclic epoxy resin.

13. A manufacturing method for a liquid ejection head including an ejection orifice and a film containing a condensate of hydrolyzable silane compounds on a surface in which the ejection orifice is formed, the manufacturing method comprising:
forming, on a base material, a layer containing a condensate of a hydrolyzable silane compound having an epoxy group and a hydrolyzable silane compound having a fluorine-containing group, and a solvent; and
curing the layer,
the solvent containing one of ethanol and methanol serving as a first alcohol component, and at least one kind of alcohol having a boiling point of from 90° C. to 200° C. serving as a second alcohol component, the solvent having a content of the second alcohol component of from 2.00 mass % to 60.00 mass %,
the condensate having a degree of condensation of from 20% to 80%.

14. A manufacturing method according to claim 13, wherein the first alcohol component comprises ethanol.

15. A manufacturing method according to claim 13, wherein the second alcohol component comprises at least one kind selected from n-propanol, n-butanol, 2-butanol, and 2-methyl-1-propanol.

16. A manufacturing method according to claim 13, wherein the hydrolyzable silane compound having a fluorine-containing group comprises a hydrolyzable silane compound having a perfluoro(poly)ether group.

17. A manufacturing method according to claim 13, wherein a surface of the base material on which the layer is to be formed comprises a resin layer in an uncured state containing a photocurable epoxy resin and a photopolymerization initiator.

18. A manufacturing method according to claim 17, wherein the photocurable epoxy resin comprises one of a novolac-type epoxy resin and a bisphenol A-type epoxy resin.

19. A manufacturing method according to claim 13, wherein the layer contains a photocurable epoxy resin and a photopolymerization initiator.

20. A manufacturing method according to claim 19, wherein the photocurable epoxy resin comprises a polyfunctional alicyclic epoxy resin.
